(19) United States
(12) Patent Application Publication
(10) Pub. No.: US 2026/0239902 A1
(43) Pub. Date: Aug. 13, 2026

(54) SUBSTRATE PROCESSING METHOD, METHOD OF MANUFACTURING SEMICONDUCTOR DEVICE, METHOD OF FORMING HARD MASK, SUBSTRATE PROCESSING APPARATUS AND NON-TRANSITORY COMPUTER-READABLE RECORDING MEDIUM

(71) Applicant: Kokusai Electric Corporation, Tokyo (JP)

(72) Inventors: Gen SHIKIDA, Toyama (JP); Toshio KUDO, Toyama (JP); Hideharu ITATANI, Toyama (JP)

(21) Appl. No.: 19/637,518

(22) Filed: Apr. 2, 2026

Related U.S. Application Data
(63) Continuation of application No. PCT/JP2024/033989, filed on Sep. 24, 2024.

(30) Foreign Application Priority Data
Mar. 13, 2024 (JP) 2024-038963

(51) Int. Cl. H10P 30/22; C23C 16/56; H10D 30/01; H10D 62/00; H10P 30/20; H10P 30/28; H10P 72/00; H10P 76/40

(52) U.S. Cl. CPC H10P 30/22; C23C 16/56; H10P 30/2042; H10P 30/28; H10P 72/0402; H10P 76/405; H10P 76/4085; H10D 30/0297; H10D 62/054; H10P 30/206

(57) ABSTRACT

There is provided a technique that includes: (a) forming a multilayer film of a predetermined thickness with a controlled grain size on a substrate by performing a cycle a predetermined number of times, and patterning the multilayer film to prepare the substrate provided with a patterned multilayer film, wherein the cycle includes: (a-1) depositing a first film by exposing the substrate provided with a drift layer formed thereon to a source gas; and (a-2) exposing the substrate to a crystal growth inhibiting gas or a predetermined gas capable of forming a second film whose film quality is different from that of the first film; and (b) performing an ion implantation using the patterned multilayer film as a hard mask, wherein the multilayer film is more easily etched than the drift layer.

### CROSS REFERENCE TO RELATED APPLICATIONS

This application is a bypass continuation application of PCT International Application No. PCT/JP 2024/033989, filed on Sep. 24, 2024, in the WIPO, the international application being based upon and claiming the benefit of priority from Japanese Patent Application No. 2024-038963, filed on Mar. 13, 2024, in the Japanese Patent Office, the entire contents of which are hereby incorporated by reference.

### TECHNICAL FIELD

The present disclosure relates to a substrate processing method, a method of manufacturing a semiconductor device, a method of forming a hard mask, a substrate processing apparatus and a non-transitory computer-readable recording medium.

### BACKGROUND

### Related Art

According to some related arts, as a part of a manufacturing process of a semiconductor device, a process of forming a polycrystalline film on a substrate may be performed. In addition, according to some related arts, as another part of the manufacturing process of the semiconductor device, a process (that is, an ion implantation process) of implanting ions to the substrate may be performed using a structure (such as a silicon film formed on the substrate) as a hard mask (also simply referred to as a “mask”).

To implant impurities deeper into the substrate with a high energy, it is preferable to increase a thickness of the mask. In addition, to prevent irreparable crystal damage, an ion implantation into a silicon carbide (SiC) substrate is performed at a high temperature. In such a case, it may be difficult to economically maintain a quality of the mask appropriate for such a process.

### SUMMARY

According to the present disclosure, there is provided a technique related to a mask capable of being used for an ion implantation of a high energy.

According to the embodiments of the present disclosure, there is provided a technique that includes: (a) forming a multilayer film of a predetermined thickness with a controlled grain size on a substrate by performing a cycle a predetermined number of times, and patterning the multilayer film to prepare the substrate provided with a patterned multilayer film, wherein the cycle includes: (a-1) depositing a first film by exposing the substrate provided with a drift layer formed thereon to a source gas; and (a-2) exposing the substrate to a crystal growth inhibiting gas or a predetermined gas capable of forming a second film whose film quality is different from that of the first film; and (b) performing an ion implantation using the patterned multilayer film as a hard mask, wherein the multilayer film is more easily etched than the drift layer.

### BRIEF DESCRIPTION OF THE DRAWINGS

FIG. 1 is a diagram schematically illustrating a cross-sectional structure of a silicon carbide (SiC) super junction MOSFET according to one or more embodiments of the present disclosure.

FIG. 2 is a flow chart schematically illustrating a method of manufacturing the SiC super junction MOSFET according to the embodiments of the present disclosure.

FIG. 3A is a diagram schematically illustrating a cross-section of a substrate at a stage in the method according to the embodiments of the present disclosure.

FIG. 3B is a diagram schematically illustrating a cross-section of the substrate at another stage in the method according to the embodiments of the present disclosure.

FIG. 3C is a diagram schematically illustrating a cross-section of the substrate at still another stage in the method according to the embodiments of the present disclosure.

FIG. 3D is a diagram schematically illustrating a cross-section of the substrate at still another stage in the method according to the embodiments of the present disclosure.

FIG. 4 is a diagram schematically illustrating a configuration of a substrate processing apparatus configured to perform a polysilicon layer (poly-Si layer) forming process in the method according to the embodiments of the present disclosure.

FIG. 5 is a functional block diagram of a controller and its related components of the substrate processing apparatus according to the embodiments of the present disclosure.

FIG. 6 is a diagram schematically illustrating a sequence of the poly-Si layer forming process in the method according to the embodiments of the present disclosure.

FIG. 7A is a diagram schematically illustrating a cross-sectional TEM image of a poly-Si layer formed as a multilayer film according to the embodiments of the present disclosure.

FIG. 7B is a diagram schematically illustrating a cross-sectional TEM image of a single poly-Si layer formed by a substrate processing according to a comparative example.

FIG. 8 is a diagram schematically illustrating measurement results of residual stress in films formed on substrates with and without an annealing step in a substrate processing according to the embodiments of the present disclosure.

FIG. 9 is a diagram schematically illustrating depth profiles of impurity concentration after an ion implantation using the poly-Si layer (according to the embodiments of the present disclosure) and using the single poly-Si layer (according to the comparative example) as masks, respectively.

### DETAILED DESCRIPTION

Hereinafter, one or more embodiments (also simply referred to as “embodiments”) according to the technique of the present disclosure will be described with reference to the drawings. The present embodiments will be described by way of an example in which a super junction structure of a silicon carbide (SiC) power metal-oxide-semiconductor field-effect transistor (MOSFET) is formed by an ion implantation. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

### (1) Structure of Super Junction Mosfet

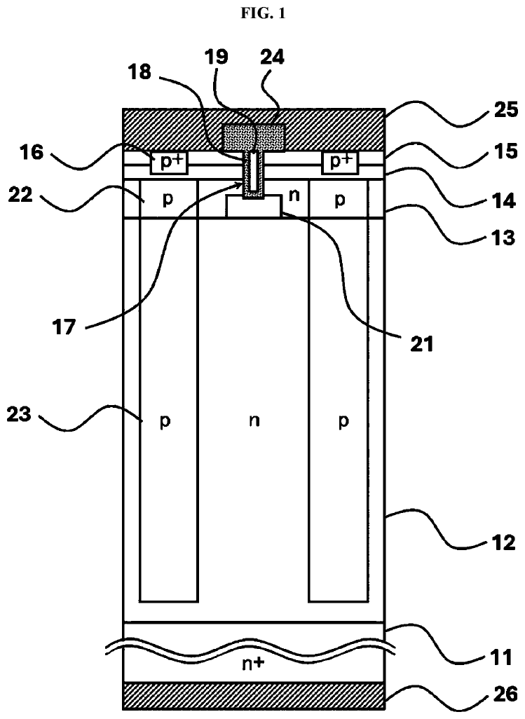

FIG. 1 is a diagram schematically illustrating a vertical cross-section of one unit cell of a super junction MOSFET serving as a semiconductor device 10. A starting substrate 11 is a wafer made of n⁺-type single crystal silicon carbide (SiC). A drift layer 12 is an n⁻-type single crystal SiC film epitaxially grown (hereafter, referred to as “epi”) on the starting substrate 11. When a voltage is applied between a source and a drain of the semiconductor device 10, the drift layer 12 serves as a region that is depleted and bears an electric field. An n-type region 13 is an n-type single crystal SiC film epitaxially grown on the drift layer 12, and functions as a so-called current spreading layer (CSL) configured to reduce a spreading resistance of a carrier.

A p-type base region 14 is a p-type single crystal SiC film epitaxially grown on the n-type region 13, and provides a channel along a gate which will be described later. An n⁺-type source region 15 is an n-type single crystal SiC film located (or disposed) on the p-type base region 14 around (on both sides of) a gate trench 17. A p⁺⁺-type contact region 16 is a p-type single crystal SiC film located on a portion of the p-type base region 14 where the n⁺-type source region 15 is not provided, in other words, a portion away from the gate trench 17 of a unit cell. A portion constituted by a single crystal SiC extending from the starting substrate 11 to the n⁺-type source region 15 and the p⁺⁺-type contact region 16 may also be referred to as a “semiconductor substrate 40”. A surface related to the n⁺-type source region 15 (and/or the p⁺⁺-type contact region 16) may also be referred to as a “front surface” (first surface) of the semiconductor substrate 40. In the present specification, the term “substrate” may refer to the “starting substrate 11” or the “starting substrate 11 with a film stacked (or laminated) thereon”. Thus, in the present specification, “forming a predetermined layer on a substrate” may refer to “forming a predetermined layer directly on a front surface of the starting substrate 11”, or may refer to “forming a predetermined layer on a surface of another layer (or another film) formed on the starting substrate 11”. In the present specification, the terms “substrate” and “wafer” may be used as substantially the same meaning.

The gate trench 17 is a groove (or a recess) extending from the front surface of the semiconductor substrate 40 and penetrating the n⁺source region 15 and the p-type base region 14 in a depth direction. The gate trench 17 also extends in a stripe pattern perpendicular to a plane of FIG. 1. A gate electrode 19 made of polysilicon (poly-Si) is embedded (or buried) in the gate trench 17 via a gate insulating film 18 made of silicon dioxide (SiO₂). A MOSFET with such a gate structure may be referred to as a “trench gate type MOSFET.” In addition, the gate electrode 19 is exposed on the front surface of the semiconductor substrate 40 via a structure such as a gate runner at both ends perpendicular to the plane of FIG. 1, and is connected to metal wiring.

A p⁺-type region 21 and a p⁺-type region 22 are diffusion regions formed by an ion implantation in a part of the SiC film (n-type single crystal SiC film) constituting the n-type region 13. The p⁺-type region 21 is located relatively deep in the n-type region 13 such that the p⁺-type region 21 is connected to and cover an entirety of a bottom surface of the gate trench 17. For example, as described above, the p⁺-type region 21 is the diffusion region formed by the ion implantation in the part of the SiC film constituting the n-type region 13. The p⁺-type region 22 is located directly below the p⁺⁺contact region 16 while separated from the p⁺-type region 21 by the n-type region 13, and penetrates the n-type region 13 in the depth direction. The p⁺-type regions 21 and 22 function to reduce (or mitigate) an electric field applied near the bottom surface of the gate trench 17.

A p-type region (also referred to as a “pillar” or a “well”) 23 is located directly below the p⁺-type region 22 and extends from an upper end (top) to a lower end (bottom) of the drift layer 12. The p-type region 23 is formed by an ion implantation into the drift layer 12. The p-type region 23 is electrically connected to a source electrode 25 described below sequentially via the p⁺⁺-type contact region 16, the p-type base region 14 and the p⁺-type region 22 in that order.

An interlayer insulating film 24 is located to cover an upper end of the gate trench 17 such that the gate is insulated from the source electrode 25. The source electrode 25 is a metal film continuously disposed over the interlayer insulating film 24 and over a portion (contact portion) of the front surface of the semiconductor substrate 40 where the interlayer insulating film 24 is not provided. The source electrode 25 forms ohmic contact with the n⁺-type source region 15 and the p⁺⁺-type contact region 16.

A drain electrode 26 is a metal film provided (or formed) over an entirety of a back surface of the starting substrate 11 (a back surface of the semiconductor substrate 40).

In an FET with such a structure, as a source-drain voltage increases during an off state, a depletion layer expands from a boundary between the drift layer 12 and the p-type region 23 into each other. Eventually, both of the drift layer 12 and the p-type region 23 are depleted. In other words, the drift layer 12 interposed between portions of the p-type region 23 is depleted laterally from both sides thereof. When a lateral thickness of the drift layer 12 reaches half a distance (spacing) between the portions of the p-type region 23, the depletion layer with a thickness equal to a depth of the p-type region 23 is obtained. Therefore, as compared with a device without a super junction structure, it is possible to increase an impurity concentration to achieve the same breakdown voltage. Thereby, it is possible to reduce an “ON resistance.” For example, the depth of the p-type region 23 is 3 μm or more, and more preferably 10 μm or more.

### (2) Method of Manufacturing Super Junction Mosfet

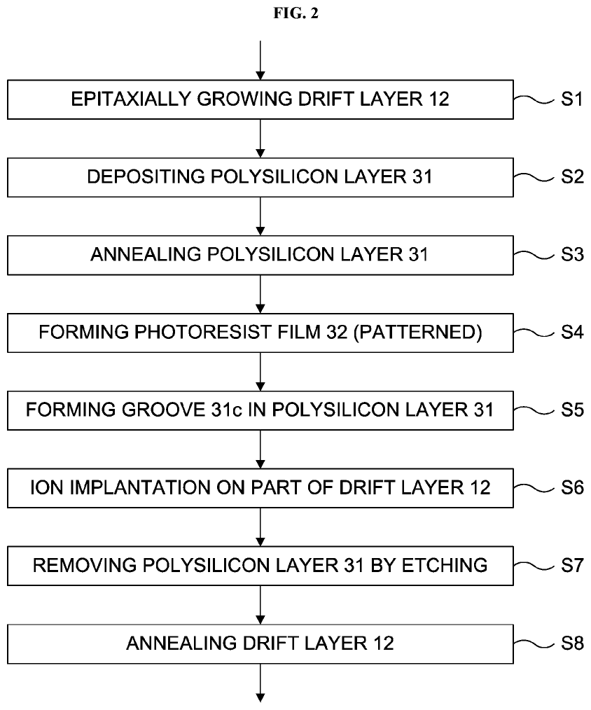

As shown in FIG. 2, first, in a step S1, the drift layer 12 is epitaxially grown on the front surface of the starting substrate 11 using an apparatus such as a single wafer type CVD apparatus. The starting substrate 11 is made of 4H—SiC, with the front surface tilted 4 degrees from (0001) plane. The drift layer 12 is of an n⁻-type, and the thickness thereof is approximately from 3 μm to 15 μm. For example, a buffer layer (which is nitrogen-doped) whose thickness is approximately 1 μm to 5 μm may be provided between the starting substrate 11 and the drift layer 12. The buffer layer converts basal plane dislocations in the starting substrate 11 into dislocations such as threading edge dislocations that are harmless to the device so as to prevent the basal plane dislocations from propagating to the drift layer 12. It is also possible to promote a recombination of minority carriers.

In general, the drift layer 12 and the p-type region 23 may be formed by a multi-stage epitaxial growth. That is, since a mask formation and the ion implantation are performed each time a thin epitaxial layer is formed, steps related thereto may become complicated. In addition, since the ion implantation roughens a surface of the drift layer 12, new defects and energy levels may be introduced into the drift layer 12. As a result, electrical characteristics of the device may be degraded. Alternatively, instead of or in addition to the ion implantation, a trench backfilling epitaxial manufacturing method is also known. However, even in such a method, steps related thereto may become complicated.

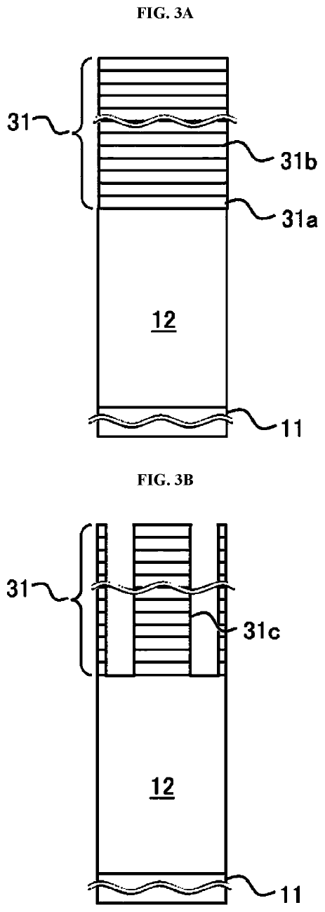

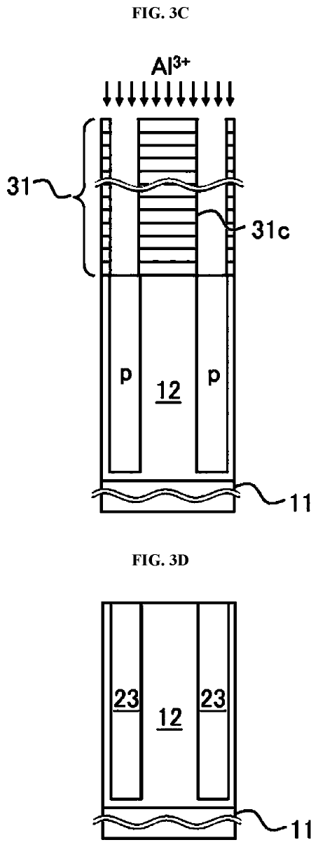

Next, in a step S2, as shown in FIG. 3A, a polysilicon layer (poly-Si layer) 31 serving as a hard mask is deposited on the drift layer 12 to a thickness of approximately from 1 μm to 20 μm. In the present specification, the term “Si” refers to a silicon element. The thickness of the poly-Si layer 31 is determined based on a desired implantation stopping power, and is, for example, approximately from 0.5 time to 1.5 times a height of the p-type region 23, that is, an implantation depth. When deposited using a hot wall type apparatus, a silicon film (Si film) is superior to a silicon nitride film (SiN film) and a silicon oxide film (SiO film) in terms of a film forming rate (deposition speed) and a reduction in a generation of particles. However, when a polysilicon film (poly-Si film) is thick, the substrate may warp due to a stress within such a film. In addition, a crystallinity of the Si film generally changes depending on a film forming temperature. However, when a crystal grain size increases in polycrystalline silicon, a channeling may occur during the ion implantation. As a result, a mask performance may be reduced. According to an example of the present embodiments, as described later, an inhibition layer inserted structure (ILIS) is used to achieve a low stress and a small grain size by forming the Si film using a single process furnace. For example, as an etch stopper or the buffer layer, a silicon dioxide layer (SiO₂ layer) or a trisilicon tetranitride layer (Si₃N₄ layer) whose thickness is approximately 20 nm may be formed between the drift layer 12 and the poly-Si layer 31.

Subsequently, in a step S3, the poly-Si layer 31 is annealed (heat soaked) to appropriately relieve (or mitigate) the stress in the substrate on which the poly-Si layer 31 is formed. The poly-Si layer 31 in an as-deposited state retains a compressive stress therein. However, when annealed, an excess Si atom within the poly-Si layer 31 is incorporated into the crystal. Thereby, a volume thereof is reduced and a residual stress thereof is shifted to a tensile stress. When an absolute value of the residual stress is large, the poly-Si layer 31 remained when a groove 31c is formed by a subsequent etching step may tilt, or the substrate may warp such that a subsequent step such as a photolithography step is interfered. On the contrary, when such a problem does not occur, the step S3 of annealing the poly-Si layer 31 may be omitted.

Subsequently, in a step S4, a photoresist film 32 patterned by the photolithography step is formed on the poly-Si layer 31. Specifically, a photoresist material is applied, cured, exposed, developed and cleaned (washed). The photoresist film 32 is formed over an entirety of the poly-Si layer 31 except for an area directly above where the p-type region 23 is to be formed.

Subsequently, in a step S5, using the photoresist film 32 as a mask, the poly-Si layer 31 is anisotropically etched using a Bosch process to form the groove 31c in the poly-Si layer 31, as shown in FIG. 3B. It is preferable that a width of the groove 31c is approximately from 0.5 μm to 3 μm and a depth of the groove 31c is equal to the thickness of the poly-Si layer 31. An aspect ratio of the groove 31c may reach 10 to 20. For example, a distance (spacing) between adjacent grooves 31c is approximately from 1 μm to 5 μm. In the Bosch process, a passivation step (in which the substrate is exposed to a plasma generated in a C₄F₈ gas atmosphere, and a CF-based polymer film is isotropically deposited) and a step (in which the substrate is exposed to a plasma generated in an SF₆ gas atmosphere, and the substrate is etched predominantly in a direction perpendicular to the surface of the substrate) are alternately and repeatedly performed for several seconds to several tens of seconds. An apparatus capable of performing such an etching is provided with an etching endpoint detection system configured to detect an exposure of a base layer (underlying layer) by analyzing a plasma emission spectrum to identify elements in the atmosphere. Since silicon (Si) is more easily etched (that is, more susceptible to etching) than silicon carbide (SiC), such a process is much easier than a process of directly forming a groove in the drift layer 12 for embedding the p-type region 23. In addition, it is possible to etch as deep as 20 μm in one execution. The photoresist film 32 remained after such an etching is removed as appropriate.

Subsequently, in a step S6, the ion implantation is performed on the drift layer 12 using the poly-Si layer 31 (which remains after the step S5) as the hard mask, as shown in FIG. 3C. In the ion implantation, atoms (such as aluminum atoms or boron atoms (Group 3 elements)) serving as an acceptor later are ionized and accelerated with an energy of 1 MeV to 20 MeV. Ions (which are ionized from the atoms) are implanted perpendicular to (1000) plane of the starting substrate 11. During such an implantation, the substrate including the drift layer 12 is heated and maintained at approximately 500° C. The ions entering the drift layer 12 undergo the channeling, penetrating deep into the drift layer 12 along a crystal lattice. On the other hand, the ions entering the poly-Si layer 31 are decelerated and captured within the poly-Si layer 31, and do not substantially reach the drift layer 12.

According to an example of the present embodiments, since the ions are implanted deep into the drift layer 12, the ion implantation is performed with a very high energy. To mitigate the damage to the drift layer 12, with the substrate heated to approximately 400° C. to 650° C., the ion implantation is performed. For example, when forming a p-type pillar for a p-type MOSFET, a Group 5 element such as nitrogen and phosphorus may be used.

Subsequently, in a step S7, the poly-Si layer 31 (which becomes unnecessary after the step S6) is completely removed by an etching. As the etching, for example, a wet etching using a hydrofluoric nitric acid (a mixture of HF and HNO₃) solution or a tetramethylammonium hydroxide solution may be used.

Subsequently, in a step S8, the substrate including the drift layer 12 is annealed to activate impurities implanted as described above such that the p-type region 23 (in which a conductivity type is inverted from n-type to p-type) is formed as shown in FIG. 3D. Such an annealing is performed using a vertical type and batch type furnace at 700° C. to 1,800° C. in an inert gas atmosphere or a silicon-containing gas atmosphere for several minutes to several tens of hours. For example, a cap layer may be formed to protect the surface of the drift layer 12 before such an annealing.

Since subsequent steps are similar to those in a conventional manufacturing method, the description related thereto will be omitted.

### (3) Film Forming Apparatus Used to Form Poly-Si Layer

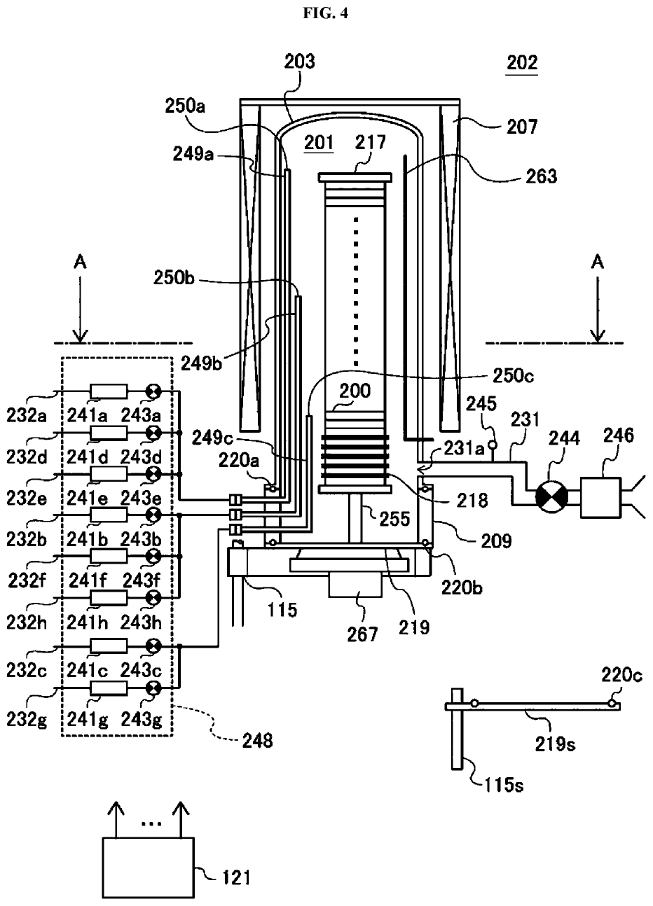

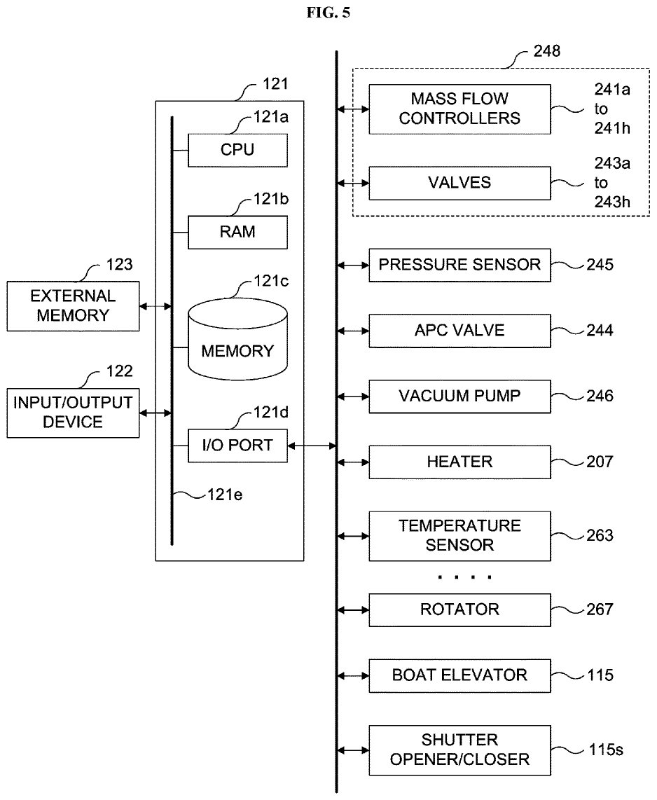

Subsequently, a configuration of a substrate processing apparatus used to form the poly-Si layer 31 in the step S2 will be described. As shown in FIG. 4, a process furnace 202 of the substrate processing apparatus includes a heater 207 serving as a temperature regulator (which is a temperature adjusting structure or a heating structure). The heater 207 is of a cylindrical shape, and is vertically installed while being supported by a support plate (not shown). The heater 207 also functions as an activator (also referred to as an “exciter”) capable of activating (or exciting) a gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). For example, the reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal material such as stainless steel (SUS). For example, the manifold 209 is of a cylindrical shape with open upper and lower ends. An upper end portion of the manifold 209 is engaged with a lower end portion of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to be capable of accommodating a plurality of wafers 200. Hereinafter, each of the plurality of wafers 200 may also be referred to as a “wafer 200” serving as the substrate. The wafer 200 is processed in the process chamber 201.

Nozzles 249a, 249b and 249c are provided in the process chamber 201 so as to penetrate a side wall of the manifold 209. The nozzles 249a, 249b and 249c may serve as a first supply structure, a second supply structure and a third supply structure, respectively. The nozzles 249a, 249b and 249c may also be referred to as a first nozzle, a second nozzle and a third nozzle, respectively. For example, each of the nozzles 249a, 249b and 249c is made of a heat resistant material such as quartz. Gas supply pipes 232a, 232b and 232c are connected to the nozzles 249a, 249b and 249c, respectively. Lengths of the nozzles 249a, 249b and 249c are set to be different.

The nozzle 249a is installed in the process chamber 201 so as to extend along a wafer arrangement direction to a position in the vicinity of an upper end (top) of a wafer arrangement region (wafer arrangement area) from a lowermost wafer among the wafers 200 to an uppermost wafer among the wafers 200. The nozzle 249c is installed in the process chamber 201 so as to extend along the wafer arrangement direction to a position in the vicinity of a lower end (bottom) of the wafer arrangement region. The nozzle 249b is installed in the process chamber 201 so as to extend along the wafer arrangement direction to a position in the vicinity of a center of the wafer arrangement region. The nozzles 249a and 249c are installed adjacent to the nozzle 249b. Gas supply holes 250a, 250b and 250c through which gases are respectively supplied are provided at front ends (tips) of the nozzles 249a to 249c, respectively.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. Gas supply pipes 232d and 232e are connected to the gas supply pipe 232a at a downstream side of the valve 243a. Gas supply pipes 232f and 232h are connected to the gas supply pipe 232b at a downstream side of the valve 243b. A gas supply pipe 232g is connected to the gas supply pipe 232c at a downstream side of the valve 243c. MFCs 241d, 241e, 241f, 241g and 241h and valves 243d, 243e, 243f, 243g and 243h are sequentially installed at the gas supply pipes 232d, 232e, 232f, 232g and 232h, respectively, in this order from upstream sides to downstream sides of the gas supply pipes 232d, 232e, 232f, 232g and 232h in the gas flow direction. For example, each of the gas supply pipes 232a to 232h is made of a metal material such as stainless steel (SUS).

A source gas is supplied into the process chamber 201 through the gas supply pipes 232a to 232c provided with the MFCs 241a to 241c and the valves 243a to 243c, respectively, and the nozzles 249a to 249c. The source gas may also be referred to as a “first element-containing gas,” that is, a gas containing a first element as a source material.

A cleaning gas is supplied into the process chamber 201 through the gas supply pipe 232d provided with the MFC 241d and the valve 243d and the nozzle 249a.

An inert gas is supplied into the process chamber 201 through the gas supply pipes 232e to 232g provided with the MFCs 241e to 241g and the valves 243e to 243g, respectively, the gas supply pipes 232a to 232c and the nozzles 249a to 249c.

A crystal growth inhibiting gas (which affects a crystal growth of the source gas) is supplied into the process chamber 201 through the gas supply pipe 232h provided with the MFC 241h and the valve 243h, the gas supply pipe 232b and the nozzle 249b.

A source gas supplier (which is a source gas supply system) is constituted mainly by the gas supply pipes 232a to 232c, the MFCs 241a to 241c and the valves 243a to 243c. The source gas supplier may also be referred to as a “film forming gas supplier” which is a film forming gas supply system. A cleaning gas supplier (which is a cleaning gas supply system) is constituted mainly by the gas supply pipe 232d, the MFC 241d and the valve 243d. An inert gas supplier (which is an inert gas supply system) is constituted mainly by the gas supply pipes 232e to 232g, the MFCs 241e to 241g and the valves 243e to 243g. A crystal growth inhibiting gas supplier (which is a crystal growth inhibiting gas supply system) is constituted mainly by the gas supply pipe 232h, the MFC 241h and the valve 243h.

According to the present embodiments, since the source gas acts as a film-forming gas or the first element-containing gas, the source gas supplier may also be referred to as the “film forming gas supplier” or a “first element-containing gas supplier” which is a first element-containing gas supply system.

Any one or an entirety of the gas suppliers described above may be configured as an integrated gas supply system 248 in which components such as the valves 243a to 243h and the MFCs 241a to 241h are integrated. The integrated gas supply system 248 is connected to each of the gas supply pipes 232a to 232h. Operations of the integrated gas supply system 248 to supply various gases to the gas supply pipes 232a to 232h, for example, operations such as operations of opening and closing the valves 243a to 243h and operations of adjusting flow rates of various gases by the MFCs 241a to 241h may be controlled by a controller 121 described later. The integrated gas supply system 248 may be embodied as an integrated structure (integrated unit) of an all-in-one type or a divided type. The integrated gas supply system 248 can be attached to or detached from the components such as the gas supply pipes 232a to 232h on a basis of the integrated structure. Operations such as maintenance, replacement and addition for the integrated gas supply system 248 can be performed on the basis of the integrated structure.

An exhaust port 231a through which an atmosphere (inner atmosphere) of the process chamber 201 is exhausted is provided at a lower side wall of the reaction tube 203. The exhaust port 231a may be provided at a location so as to face (or opposite to) the nozzles 249a to 249c (that is, the gas supply holes 250a to 250c) with the wafer 200 interposed therebetween. The exhaust port 231a may be provided so as to extend along a side wall of the manifold 209, or may be provided so as to extend along the side wall of the reaction tube 203 from a lower portion to an upper portion thereof (that is, along the wafer arrangement region). An exhaust pipe 231 is connected to the exhaust port 231a. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) configured to detect a pressure (inner pressure) of the process chamber 201, and the APC valve 244 serves as a pressure regulator (pressure adjusting structure). With the vacuum pump 246 in operation, the APC valve 244 may be opened or closed to perform a vacuum exhaust operation for the process chamber 201 or stop the vacuum exhaust operation. In addition, with the vacuum pump 246 in operation, the inner pressure of the process chamber 201 may be adjusted by adjusting an opening degree of the APC valve 244 based on pressure information detected by the pressure sensor 245. An exhauster (which is an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing (closing) a lower end opening of the manifold 209 is provided under the manifold 209. For example, the seal cap 219 is made of a metal material such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate a boat 217 described later is provided under the seal cap 219. For example, a rotating shaft 255 of the rotator 267 is connected to the boat 217 through the seal cap 219. The rotator 267 is configured to rotate the wafers 200 accommodated in the boat 217 by rotating the boat 217. The seal cap 219 is configured to be elevated or lowered in a vertical direction by a boat elevator 115 serving as an elevating structure provided outside the reaction tube 203. The boat elevator 115 serves as a transfer apparatus (which is a transfer structure) capable of transferring (loading) the wafers 200 into the process chamber 201 and capable of transferring (unloading) the wafers 200 out of the process chamber 201 by elevating and lowering the seal cap 219.

A shutter 219s serving as a furnace opening lid capable of airtightly sealing (closing) the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 serving as a substrate support is configured such that the wafers 200 (for example, 25 wafers to 200 wafers) are supported (or stacked) in the vertical direction in the boat 217 while the wafers 200 are horizontally oriented with their centers aligned with one another in a multistage manner. That is, the boat 217 is configured such that the wafers 200 are arranged in the vertical direction in the boat 217 while the wafers 200 are stacked in the vertical direction with a predetermined interval therebetween. For example, the boat 217 is made of a heat resistant material such as quartz and SiC. For example, a plurality of heat insulation plates 218 are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of a temperature (inner temperature) of the process chamber 201 can be obtained. The temperature sensor 263 is provided along an inner wall of the reaction tube 203.

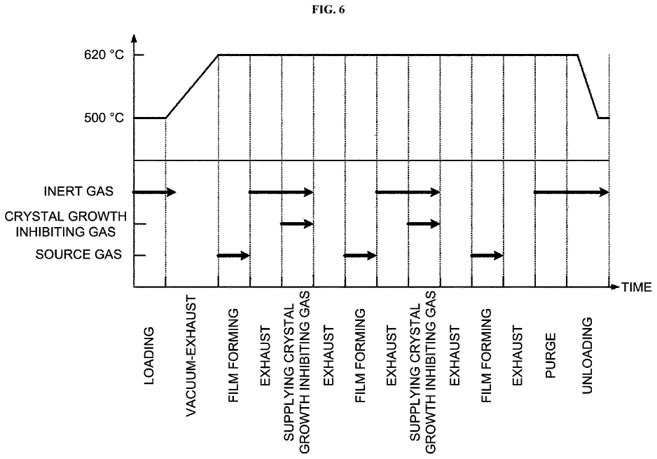

As shown in FIG. 5, the controller 121 serving as a control structure (control apparatus) is constituted by a computer including a CPU (Central Processing Unit) 121a, a RAM (Random Access Memory) 121b, a memory 121c and an I/O port (input/output port) 121d. The RAM 121b, the memory 121c and the I/O port 121d are configured to be capable of exchanging data with the CPU 121a through an internal bus 121e. For example, an input/output device 122 constituted by a component such as a touch panel is connected to the controller 121.

For example, the memory 121c is configured by a component such as a flash memory, a hard disk drive (HDD) and a solid state drive (SSD). For example, a control program configured to control an operation of the substrate processing apparatus and a process recipe containing information on procedures and conditions of a substrate processing described later may be readably stored in the memory 121c. The process recipe is obtained by combining steps (procedures) of the substrate processing described later such that the controller 121 can execute the steps by the substrate processing apparatus to acquire a predetermined result, and functions as a program. Hereinafter, the process recipe and the control program may be collectively or individually referred to as a “program.” In addition, the process recipe may also be simply referred to as a “recipe.” Thus, in the present specification, the term “program” may refer to the recipe alone, may refer to the control program alone or may refer to both of the recipe and the control program. The RAM 121b functions as a memory area where a program or data read by the CPU 121a is temporarily stored.

The I/O port 121d is connected to the components described above such as the MFCs 241a to 241h, the valves 243a to 243h, the pressure sensor 245, the APC valve 244, the vacuum pump 246, the temperature sensor 263, the heater 207, the rotator 267, the boat elevator 115 and the shutter opener/closer 115s.

The CPU 121a is configured to read the control program from the memory 121c and execute the control program read from the memory 121c. In addition, the CPU 121a is configured to read the recipe from the memory 121c, for example, in accordance with an operation command inputted from the input/output device 122. In accordance with contents of the recipe read from the memory 121c, the CPU 121a may be configured to be capable of controlling various operations such as flow rate adjusting operations for various gases by the MFCs 241a to 241h, opening and closing operations of the valves 243a to 243h, an opening and closing operation of the APC valve 244, a pressure adjusting operation by the APC valve 244 based on the pressure sensor 245, a start and stop operation of the vacuum pump 246, a temperature adjusting operation by the heater 207 based on the temperature sensor 263, an operation of adjusting a rotation and a rotation speed of the boat 217 by the rotator 267, an elevating and lowering operation of the boat 217 by the boat elevator 115 and an opening and closing operation of the shutter 219s by the shutter opener/closer 115s.

The controller 121 may be embodied by installing the above-described program stored in an external memory 123 into the computer. For example, the external memory 123 may include a magnetic disk such as a hard disk drive (HDD), an optical disk such as a CD, a magneto-optical disk such as an MO and a semiconductor memory such as a USB memory and a solid state drive (SSD). The memory 121c or the external memory 123 may be embodied by a non-transitory computer readable recording medium. Hereafter, the memory 121c and the external memory 123 may be collectively or individually referred to as a “recording medium”. Thus, in the present specification, the term “recording medium” may refer to the memory 121c alone, may refer to the external memory 123 alone, or may refer to both of the memory 121c and the external memory 123. Instead of the external memory 123, a communication interface such as the Internet and a dedicated line may be used for providing the program (also referred to as a “program product”) to the computer.

### (4) Step of Forming Poly-Si Layer

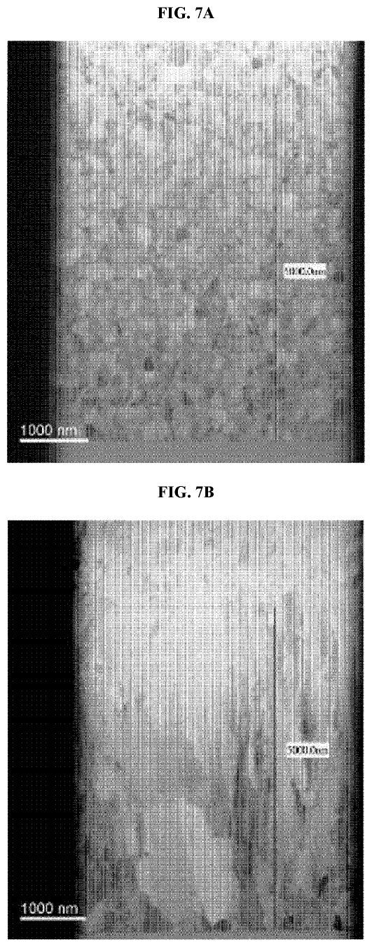

Subsequently, with reference to FIGS. 6, 7A and 7B, a substrate processing method of forming the poly-Si layer 31 by performing the steps S2 and S3 using the substrate processing apparatus mentioned above will be described. In the following description, operations of components constituting the substrate processing apparatus are controlled by the controller 121. In an example according to the present embodiments, the poly-Si layer 31 is formed as a multilayer film as shown in FIG. 7A by alternately supplying the source gas and the crystal growth inhibiting gas.

That is, in a film forming step (that is, the step of forming the poly-Si layer 31), a step C of forming the multilayer film of a predetermined thickness serving as the poly-Si layer 31 on the wafer 200 is performed. The step C is performed by performing a cycle a predetermined number of times (n times, n is an integer of 1 or more). The cycle includes: a step A of depositing a polycrystalline film serving as a primitive film (initial film) by exposing the substrate (that is, the wafer 200) to the source gas, wherein the starting substrate 11 on which the drift layer 12 is formed in advance is prepared as the wafer 200; and a step B of exposing the substrate (that is, the wafer 200) to the crystal growth inhibiting gas. In addition, the step B is performed under conditions such that the polycrystalline film deposited in a subsequent execution of the step A can form new crystal grains.

### Wafer Charging Step and Boat Loading Step

When the plurality of wafers 200 are charged (loaded or transferred) into the boat 217, the shutter 219s is moved by the shutter opener/closer 115s to open the lower end opening of the manifold 209. Then, as shown in FIG. 4, the boat 217 supporting the plurality of wafers 200 is elevated by the boat elevator 115 and loaded (transferred) into the process chamber 201. Finally, the seal cap 219 airtightly seals the process chamber 201 via the O-ring 220b. In such an operation, the inert gas is supplied into the process chamber 201, and the inner temperature of the process chamber 201 is maintained at a desired temperature.

### Vacuum-Exhausting Step and Temperature Adjusting Step

Thereafter, the vacuum pump 246 vacuum-exhausts (decompresses and exhausts) an inside (inner portion) of the process chamber 201 (that is, a space in which the wafers 200 are present (accommodated)) such that the inner pressure of the process chamber 201 reaches and is maintained at a desired pressure (vacuum degree). In such an operation, the inner pressure of the process chamber 201 is measured by the pressure sensor 245, and the APC valve 244 is feedback-controlled based on the pressure information detected by the pressure sensor 245. In addition, the heater 207 heats the process chamber 201 such that a temperature of the wafer 200 in the process chamber 201 reaches and is maintained at a desired process temperature. In such an operation, the state of the electric conduction to the heater 207 is feedback-controlled based on the temperature information detected by the temperature sensor 263 such that a desired temperature distribution of the inner temperature of the process chamber 201 can be obtained. In addition, a rotation of the wafer 200 is started by the rotator 267. The vacuum pump 246 continuously vacuum-exhausts the inside of the process chamber 201, the heater 207 continuously heats the wafer 200 in the process chamber 201 and the rotator 267 continuously rotates the wafer 200 until at least a processing of the wafer 200 is completed.

Then, the step A and step B are performed in this order. Each of the steps A and B is described below.

### Step A

In the step A, the source gas is supplied to the wafer 200 in the process chamber 201. By exposing the wafer 200 to the source gas, the polycrystalline film (polycrystalline film 31a) is deposited on the surface of the wafer 200. Thereafter, a supply of the source gas is stopped, and the source gas remaining in the process chamber 201 is exhausted (purged).

Specifically, the valves 243a to 243c are opened to supply the source gas into the gas supply pipes 232a to 232c. A flow rate of the source gas is adjusted by each of the MFCs 241a to 241c, and the source gas whose flow rate is adjusted is supplied into the process chamber 201 through the nozzles 249a to 249c and exhausted through the exhaust port 231a. Thereby, the source gas is supplied and exposed to the wafer 200. In such an operation, the inner pressure of the process chamber 201 is maintained at a predetermined process pressure by the APC valve 244.

By supplying the source gas to the wafer 200 under process conditions described below, the primitive film (initial film) is deposited on the surface of the wafer 200 by a thermal CVD method to form the polycrystalline film 31a. For example, the polycrystalline film 31a is a film containing a Group 14 element such as silicon and germanium (Ge). According to the present embodiments, a hot wall type process chamber (that is, a hot wall type and batch type process chamber) is used as the process chamber 201. Therefore, in contrast to a cold wall type process chamber, the thermal CVD method often involves a gas phase reaction. A quality of the film (also referred to as “film quality”) obtained using such a process chamber may vary depending on a type of each process chamber. For example, as compared with an epi poly-Si film manufactured in a cold wall type and single wafer type apparatus, an absolute stress or a stress gradient of the poly-Si film (which is manufactured in a hot wall type low pressure CVD apparatus) tends to increase. Abundant reaction intermediates supplied by the gas phase reaction are useful for forming a film with a high quality at a low temperature, but they may also generate excess atoms as described later. Thereby, the residual stress may be increased.

As the source gas, for example, a gas capable of depositing the polycrystalline film 31a on the wafer 200 may be used. As the source gas, for example, a gas containing a Group 14 element, such as a silicon-containing gas (that is, a gas containing silicon) may be used. As the silicon-containing gas, for example, a monosilane (SiH₄)-containing gas may be used. When the SiH₄ gas is used as the source gas, the SiH₄ gas is thermally decomposed in the present step to form the poly-Si film (which is the polycrystalline film) on the surface of the wafer 200. In addition to or instead of the silicon-containing gas, the source gas may also contain a reducing gas, a carrier gas or a dilution gas. For example, the source gas may also contain a gas such as hydrogen (H₂) gas, nitrogen (N₂) gas, helium (He) gas and argon (Ar) gas.

For example, the process conditions when supplying the source gas in the step A are as follows:
A process temperature: from 400° C. to 1,000° C., preferably from 500° C. to 750° C., for example 620° C.;
A process pressure: from 1 Pa to 100,000 Pa, preferably from 10 Pa to 1,000 Pa;
A supply flow rate of the source gas: from 10 sccm to 5,000 sccm, preferably from 100 sccm to 1,500 sccm;
A film forming rate: from 0.1 nm/min to 30 nm/min, preferably from 1 nm/min to 20 nm/min; and
A supply flow rate of the inert gas (for each gas supply pipe): from 0 sccm to 3,000 sccm.

At a final stage of the step A, the valves 243a to 243c are closed to stop the supply of the source gas into the process chamber 201. Then, the process chamber 201 is vacuum-exhausted to remove a substance (such as the source gas remaining in the process chamber 201) out of the process chamber 201. In such an operation, the inert gas may be supplied into the process chamber 201 through the nozzles 249a to 249c. The inert gas supplied through the nozzles 249a to 249c acts as the purge gas. Thereby, the inside of the process chamber 201 is purged.

As the inert gas, for example, nitrogen (N₂) gas may be used. In addition to or instead of the N₂ gas, a rare gas such as argon (Ar) gas, helium (He) gas, neon (Ne) gas and xenon (Xe) gas may be used. The same also applies to each step described below.

For example, process conditions when purging the process chamber 201 in the step A are as follows:
A process temperature: from 400° C. to 1,000° C., preferably the same temperature as when the source gas is supplied;
A process pressure: from 1 Pa to 5,000 Pa, preferably from 5 Pa to 1,000 Pa;
A supply flow rate of the inert gas (for each gas supply pipe): from 0.1 sccm to 5,000 sccm; and
A supply time (time duration) of supplying the inert gas: from 1 second to 3,000 seconds.

In the present specification, a notation of a numerical range such as “from 1 Pa to 100,000 Pa” means that a lower limit and an upper limit are included in the numerical range. Therefore, for example, the numerical range “from 1 Pa to 100,000 Pa” means a range equal to or higher than 1 Pa and equal to or less than 100,000 Pa. The same also applies to other numerical ranges described in the present specification. In addition, in the present specification, the term “process temperature” may refer to the “temperature of the wafer 200” or the “inner temperature of the process chamber 201”, and the term “process pressure” may refer to the inner pressure of the process chamber 201. In addition, the term “process time” may refer to a time duration of continuously performing a process related thereto. The same also applies to the following description.

### Step B

After the step A is completed, the step B is performed. In the step B, the crystal growth inhibiting gas and the inert gas are supplied to the wafer 200 in the process chamber 201. That is, the wafer 200 with the polycrystalline film 31a formed on the surface thereof is exposed to the crystal growth inhibiting gas. By exposing the wafer 200 to the crystal growth inhibiting gas, a crystal growth inhibition layer (also called a crystal growth inhibition film) 31b is formed on the surface of the wafer 200 with the polycrystalline film 31a formed thereon. Thereafter, a supply of the crystal growth inhibiting gas and a supply of the inert gas are stopped, and the crystal growth inhibiting gas and the inert gas remaining in the process chamber 201 are exhausted.

Specifically, the valve 243h is opened to supply the crystal growth inhibiting gas into the gas supply pipe 232b. A flow rate of the crystal growth inhibiting gas is adjusted by the MFC 241h, and the crystal growth inhibiting gas whose flow rate is adjusted is supplied into the process chamber 201 through the nozzle 249b and exhausted through the exhaust port 231a. Thereby, the crystal growth inhibiting gas is supplied and exposed to the wafer 200 with the polycrystalline film 31a formed on the surface thereof. In such an operation, with the valves 243e to 243g open, the inert gas is supplied into the process chamber 201 through each of the nozzles 249a to 249c.

By supplying the crystal growth inhibiting gas to the wafer 200 under process conditions described below and exposing the wafer 200 to the crystal growth inhibiting gas, the crystal growth inhibition layer 31b containing an element other than those constituting the polycrystalline film 31a is formed on the surface of the polycrystalline film 31a formed in the immediately preceding Step A. The crystal growth inhibition layer 31b stops a continuous crystal growth of microcrystals (crystal grains) constituting the polycrystalline film 31a.

The step B is performed under conditions in which the polycrystalline film 31a deposited in the subsequent execution of the step A can form new crystal grains. That is, by exposing the wafer 200 with the polycrystalline film 31a formed on the surface thereof to the crystal growth inhibiting gas, the polycrystalline film 31a deposited in the subsequent execution of the step A can form new crystal grains. In other words, by performing the step B, grain boundaries of the polycrystalline film 31a formed on the surface of the wafer 200 can be terminated by the crystal growth inhibition layer 31b, crystal nuclei at a predetermined density can be formed in the polycrystalline film 31a deposited in the subsequent execution of the step A, and independent crystals (which are not continuous with underlying crystals) can grow. The crystal growth inhibition layer 31b is not limited to that formed during the step B, but may include an amorphous layer or other low crystalline layer to be formed at an initial stage in the subsequent execution of the step A.

A thickness of the film (or a layer) (that is, the crystal growth inhibition layer 31b) formed in the step B is set to be thinner than a thickness of the polycrystalline film 31a formed in the immediately preceding Step A, for example, 1/10 or less of the thickness of the polycrystalline film 31a formed in the immediately preceding Step A. Alternatively, the step B may modify or remove a part of the film (that is, the polycrystalline film 31a) formed in the immediately preceding Step A, or may change (reconstruct) a surface state of the film formed in the immediately preceding Step A.

Subsequently, the valve 243h and the valves 243e to 243g are closed to stop the supply of the crystal growth inhibiting gas and the supply of the inert gas into the process chamber 201. Then, the process chamber 201 is vacuum-exhausted to remove a substance (such as the crystal growth inhibiting gas and the inert gas remaining in the process chamber 201) out of the process chamber 201.

For example, the process conditions when supplying the crystal growth inhibiting gas in the step B are as follows:
A process pressure: from 1 Pa to 10,000 Pa, preferably from 1 Pa to 1,000 Pa;
A supply flow rate of the crystal growth inhibiting gas: from 0.1 sccm to 5,000 sccm, preferably from 10 sccm to 500 sccm;
A supply time (time duration) of supplying the crystal growth inhibiting gas: from 0.1 second to 30 minutes, preferably from 1 second to 3 minutes; and
A supply flow rate of the inert gas (for each gas supply pipe): from 0 sccm to 3,000 sccm.

For example, process conditions when exhausting the process chamber 201 in the step B are as follows:
A process pressure: from 0.1 Pa to 5,000 Pa, preferably from 10 Pa to 1,000 Pa.

In addition, in the step B, an output of the heater 207 is adjusted such that the step B is performed at the process temperature the same as the process temperature in the step A. The process temperature is set to be lower than a substrate temperature (typically 1,000° C. or higher) applied when manufacturing the epi poly-Si film by the cold wall type and single wafer type apparatus.

As the crystal growth inhibiting gas, for example, an oxygen (O)-containing gas or a nitrogen (N)-containing gas may be used. As the oxygen-containing gas, for example, oxygen (O₂) gas may be used. When using the oxygen-containing gas as the crystal growth inhibiting gas, at least a part of the polycrystalline film 31a formed on the surface of the wafer 200 in the step A is oxidized. Thereby, it is possible to form a layer (serving as the crystal growth inhibition layer 31b and containing oxygen as the element other than those constituting the polycrystalline film 31a) on the surface of the polycrystalline film 31a, and it is also possible to inhibit the continuous crystal growth. In such a case, a film quality of such a layer is different from a film quality of the polycrystalline film 31a. In other words, the layer (which is oxidized) can be used as the crystal growth inhibition layer 31b capable of inhibiting the crystal growth of the polycrystalline film 31a.

In addition, the step B may be performed under conditions such that a density of the crystal nuclei formed as a result of the step B is set to be a desired areal density (for example, a density in which the crystal grain size of the polycrystalline film 31a formed thereon is at least ⅕ but less than 1 of a crystal grain size that would be obtained without the step B). Such crystal nuclei may be achieved by controlling the conditions such as an oxygen partial pressure, the process temperature and the process time when supplying the oxygen-containing gas in the step B.

### Step C

By performing the cycle wherein the step A and the step B described above are sequentially performed in this order a predetermined number of times (n times, wherein n is an integer of 1 or more), it is possible to form the multilayer film with a predetermined thickness (for example, from 1 μm to 20 μm) on a surface of a sacrificial layer (not shown) of the wafer 200. When the thickness of the multilayer film is less than 1 μm, it may be difficult to form a well of a sufficient depth for a super lattice structure by the ion implantation. On the contrary, when the thickness of the multilayer film is greater than 20 μm, a stopping power may become excessive with respect to a commercially available ion implantation energy (currently, about 15 MeV), and a risk of deterioration of the perpendicularity of a side surface of the mask may also increase. It is preferable that the cycle described above is repeatedly performed a plurality number of times, more preferably, three or more times. Specifically, the crystal growth inhibition layer 31b is formed every time the polycrystalline film 31a is formed to a thickness of, for example, from 100 nm to 500 nm, more specifically, 250 nm. Thereby, on the surface of the sacrificial layer (not shown) of the wafer 200, it is possible to form the multilayer film whose thickness is, for example, from 1 μm to 20 μm, more preferably, from 1 μm to 10 μm. That is, a plurality of polycrystalline films including the polycrystalline film 31a and a plurality of crystal growth inhibition layers including the crystal growth inhibition layer 31b are alternately formed. Hereinafter, the plurality of polycrystalline films including the polycrystalline film 31a may also be referred to as “polycrystalline films 31a”, and the plurality of crystal growth inhibition layers including the crystal growth inhibition layer 31b may also be referred to as “crystal growth inhibition layers 31b”. Alternatively, the step A and the step B may be performed simultaneously.

Then, after the step C, the step A described above is performed to form the polycrystalline film 31a on the crystal growth inhibition layer 31b. In other words, the polycrystalline film 31a is deposited on the crystal growth inhibition layer 31b by forming new crystal grains. In other words, between the polycrystalline film 31a located directly above the crystal growth inhibition layer 31b and the polycrystalline film 31a located directly below the crystal growth inhibition layer 31b, there is no or limited crystalline continuity. By using an electron backscatter diffraction (EBSD) analysis, when an insertion interval (insertion spacing) of the crystal growth inhibition layers 31b is 50 nm, it is possible to confirm that a weighted average grain size of each of the polycrystalline films 31a is approximately equal within a range, approximately from 160 nm to 170 nm, which is approximately three times the insertion interval of the crystal growth inhibition layers 31b.

In a manner described above, as shown in FIG. 7A, the crystal grains of the polycrystalline films 31a on the wafer 200 are separated by the crystal growth inhibition layers 31b to form the multilayer film including the polycrystalline films 31a. Hereinafter, such a structure of the multilayer film formed as described above may also be referred to as the “inhibition layer inserted structure” (ILIS), and the film forming step of forming such a structure may also be referred to as an “ILIS process”. In contrast, a conventional single film structure without the ILIS may also be referred to as a “comparative example” (see FIG. 7B). When obtaining the multilayer film of a predetermined thickness, the predetermined number of times mentioned above (also referred to as the number of times the step B is performed, or the number of the crystal growth inhibition layers 31b) may change a density of amorphous or excess silicon atoms (described below) throughout an entirety of the multilayer film. Therefore, by controlling the predetermined number of times, it is possible to control the residual stress throughout the entirety of the multilayer film.

The predetermined number of times mentioned above is set such that the absolute value of the residual stress in the multilayer film after the step (annealing step) S3 described later falls within a range of an acceptable value. The acceptable value of the residual stress in the film (that is, the multilayer film) may vary depending on the application. However, for example, the acceptable value is within a range from −150 MPa to 150 MPa. In the present specification, as the residual stress, the tensile stress is defined as positive and compressive stress as negative. In other words, by controlling the number of times the step B is performed, it is possible to control the residual stress in the multilayer film after the annealing step S3. In the present specification, the term “residual stress” refers to a stress existing within an object in an absence of external forces. In the present specification, the term “residual stress” may refer to a force acting between the multilayer film and the wafer 200 serving as a base of the multilayer film, may refer to the stress remaining in the multilayer film even after a part of the multilayer film is removed and some of the residual stress mentioned above is released, or may refer to both of them. For example, the residual stress may also be referred to as a “film stress.”

According to the present embodiments, the number of times the step B is performed in the film forming step is set to be greater as the residual stress in the film after the annealing step S3 increases, and set to be less as the residual stress in the film after the annealing step S3 decreases (that is, as the residual stress is more compressive). In other words, by controlling the number of times the step B is performed, it is possible to control the residual stress in the multilayer film, and it is also possible to relieve the residual stress in the entirety of the multilayer film.

In addition, based on the number of times the step B is performed, it is possible to control the crystal grain size of the multilayer film. In other words, by retaining crystal grains within each of the polycrystalline films 31a, at least a size of the crystal grains in a height direction is limited by a distance (spacing) between the crystal growth inhibition layers 31b. In the multilayer film formed in such a manner, the thickness of each of the polycrystalline films 31a is preferably less than, and more preferably less than one-third of, the weighted average grain size of each film. In other words, crystals that grow more horizontally than vertically are preferred. The smaller the grain size is limited in such a manner, the smaller the grain size varies. From such a point of view, it is preferable than an average grain size is within a range of 0 μm to 0.2 μm. When the average grain size exceeds such a range, the grain size may vary greatly, and a surface roughness may tend to worsen.

### Purge Step and Returning to Atmospheric Pressure Step

Then, the inert gas is supplied into the process chamber 201 through each of the nozzles 249a to 249c, and then is exhausted through the exhaust port 231a. The inert gas supplied through each of the nozzles 249a to 249c acts as the purge gas. Thereby, the inside of the process chamber 201 is purged. As a result, a substance (such as the gas remaining in the process chamber 201 and reaction by-products remaining in the process chamber 201) is removed from the process chamber 201. Thereafter, the inner atmosphere of the process chamber 201 is replaced with the inert gas, and the inner pressure of the process chamber 201 is returned to the atmospheric pressure.

### Boat Unloading Step and Wafer Charging Step

Thereafter, the seal cap 219 is lowered by the boat elevator 115 and the lower end of the manifold 209 is opened. Then, the boat 217 with the wafers 200 (which are processed and supported in the boat 217) is unloaded (transferred) out of the reaction tube 203 through the lower end of the manifold 209. After the boat 217 is unloaded, the shutter 219s is moved such that the lower end opening of the manifold 209 is sealed by the shutter 219s through the O-ring 220c. Then, the wafers 200 (which are processed) are discharged (transferred or unloaded) from the boat 217 unloaded out of the reaction tube 203.

Subsequently, in another process furnace (another process chamber), another boat is loaded, an inner pressure and an inner temperature of the another process chamber are adjusted. Subsequently, the annealing step S3 is performed.

FIG. 7A is a diagram schematically illustrating a cross-sectional TEM (Transmission Electron Microscopy) image of a poly-Si layer experimentally formed using the method mentioned above. In such an experiment, the step A of depositing a 250 nm layer on a SiO₂ film serving as the buffer layer is repeatedly performed 20 times, with the step B in between, to obtain a poly-Si multilayer with a thickness of 5 μm or more. It is confirmed that independent crystal grains are formed every 250 nm in the depth direction and that a shape of the crystal grain is small and uniform. The surface roughness (Ra) is also evaluated to be 15 nm or less. On the other hand, FIG. 7B is a diagram schematically illustrating a cross-sectional TEM image of a poly-Si layer deposited continuously without the step B according to the comparative example. In a single poly-Si layer shown in FIG. 7B, the crystals grow in a column shape. As a result, it is confirmed that a shape of the crystal grain is large and a crystal grain size varies significantly. That is, it suggests that the stopping power may vary depending on a location due to a variation in the shape of the crystal grain and an orientation thereof. In addition, the surface roughness exceeds 60 nm. Thereby, it may cause a surface scattering during the ion implantation.

Subsequently, the annealing step S3 will be described. The annealing step S3 is performed in another process furnace (ex-situ) different from the process furnace used for the film forming step. In the present step, the wafer 200 (after the multilayer film has been formed on the surface thereof) is annealed in a non-plasma N2 atmosphere. An output of a heater is adjusted such that the temperature of the wafer 200 is equal to or higher than the temperature of the wafer 200 in the film forming step and equal to or lower than 1,200° C., more preferably 900° C. or more and 1,100° C. or less. By performing such an annealing, the polycrystalline film serving as an initial film is converted into a film of different quality. In such an operation, film shrinkage may occur. Specifically, by performing such an annealing, amorphous silicon present near the grain boundaries or in the crystal growth inhibition layer 31b may integrate with adjacent crystal grains in a manner similar to a solid phase epitaxial growth. According to experimental results described later, the greater the predetermined number of times the step C is performed (the number of times the step B is performed), the higher a proportion of excess silicon in the entirety of the multilayer film, and therefore, the greater a shrinkage rate due to the annealing. In other words, the greater the predetermined number of times the step C is performed, the greater a shift in the residual stress from the compressive stress (negative) to the tensile stress (positive).

As described above, the output of the heater is adjusted such that the temperature of the wafer 200 is equal to or higher than the temperature of the wafer 200 in the film forming step and equal to or lower than 1,200° C., more preferably 900° C. or more and 1,100° C. or less.

In the annealing step S3 according to an example mentioned above, as compared with the absolute value of the residual stress in the poly-Si layer 31 before the annealing step S3, it is possible to reduce the absolute value of the residual stress in the poly-Si layer 31 formed in the film forming step (that is, the step S2) (which is performed by appropriately selecting the number of times the step B is performed) to, for example, approximately 100 MPa or less. In addition, it is possible to reduce the stress on the drift layer 12 serving as a base of the poly-Si layer 31, and it is also possible to reduce a risk of forming crystal defects caused by the stress. In addition, by reducing a stress gradient in the poly-Si layer 31, it is possible to reduce a substrate warpage, and it is also possible to facilitate a subsequent step (that is, the photolithography step). On the other hand, when the absolute value of the residual stress exceeds 100 MPa, the risk mentioned above may increase.

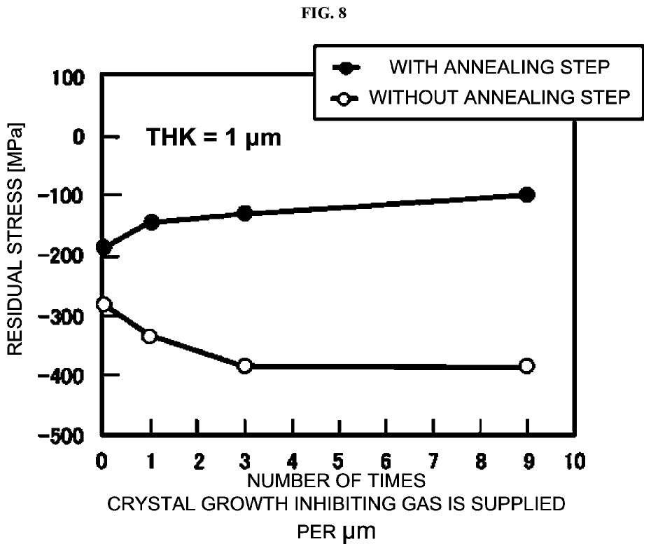

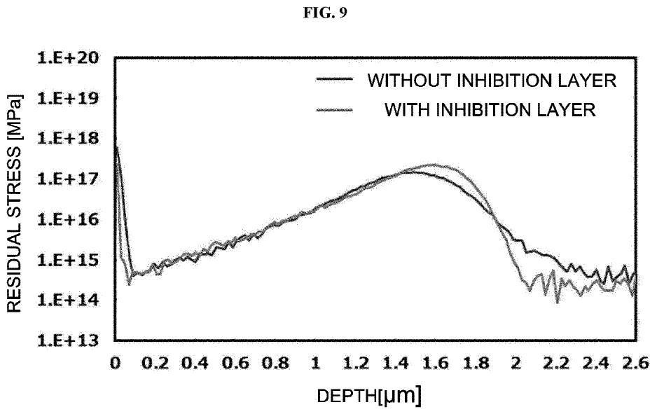

FIG. 8 is a diagram schematically illustrating a relationship between the number of times the crystal growth inhibiting gas is supplied and the residual stress in the film when a 1 μm-thick poly-Si multilayer film is formed on the wafer using the substrate processing apparatus mentioned above and the ILIS process mentioned above, in a case where the annealing step S3 is not performed after the poly-Si multilayer film is formed and a case where the annealing step S3 is performed after the poly-Si multilayer film is formed. A horizontal axis shown in FIG. 8 represents the number of times the crystal growth inhibiting gas is supplied per a 1 μm-thick film (poly-Si multilayer film), and a vertical axis shown in FIG. 8 represents the residual stress in the multilayer film. A sign of the residual stress indicates the compressive stress with a negative value and the tensile stress with a positive value. An internal stress of the multilayer film is evaluated using a substrate curvature method (in which the film is formed on both surfaces of the substrate, and then one surface of the multilayer film is peeled off for the substrate warpage to be measured). Supply times (that is, the number of times the crystal growth inhibiting gas is supplied) of 1, 3 and 9 indicate a presence of the crystal growth inhibition layer 31b at depths of 500 nm, 250 nm and 100 nm from the surface of the multilayer film, respectively.

Without the annealing step, the residual stress in the multilayer film is generally negative (that is, the compressive stress). In addition, it is confirmed that the more frequently the crystal growth inhibiting gas is supplied, the stronger the compressive stress become.

In contrast, with the annealing step, the residual stress in the multilayer film is shifted toward the tensile stress and the absolute value is smaller than a case where the annealing step is omitted, regardless of the supply times. In addition, it is confirmed that the more frequently the crystal growth inhibiting gas is supplied, the more the residual stress (the compressive stress) is shifted toward the tensile stress such that the residual stress approaches zero. In other words, it is confirmed that the absolute value of the residual stress in the multilayer film on the wafer can be reduced depending on the number of times the crystal growth inhibiting gas is supplied. In other words, a dependency of the residual stress on the number of inhibition layers (that is, the crystal growth inhibition layers 31b) is reversed between without and with the annealing step.

FIG. 9 is a diagram schematically illustrating depth profiles of impurity concentration after the ion implantation using the poly-Si layer (which is experimentally formed by a method of the present embodiments) with the inhibition layers and using a poly-Si layer (according to the comparative example) without the inhibition layers as masks, respectively. Both poly-Si layers are deposited with 2.0 μm thickness on a 20 nm SiO₂ film formed on a silicon substrate by CVD at 620° C. and 25 Pa. The inhibition layers are inserted every 200 nm. Both samples are implanted with aluminum (Al) at 1,280 keV, and analyzed by a secondary ion mass spectrometry (SIMS). In the sample of the poly-Si layer with the inhibition layers, a concentration of aluminum in the substrate serving as a base of the poly-Si layer is at a background level. That is, it is confirmed that the poly-Si layer with the inhibition layers adequately functions as the mask. In contrast, in the sample of the poly-Si layer without the inhibition layers, a concentration profile (particularly, a portion deeper than the peak) becomes gentler, and a relatively high concentration of aluminum is detected in the substrate serving as a base of the poly-Si layer.

According to the present embodiments, it is possible to obtain one or more of the following effects.
(a) By using the multilayer film with a uniform and fine grain size as the mask (implantation mask), it is possible to prevent the channeling within the mask during the ion implantation, and it is also possible to reduce a variation in the characteristics of the device manufactured as described above by improving a uniformity of the stopping power in a surface of the mask. As a result, it is possible to use a thinner mask, and it is also possible to reduce a manufacturing cost.
(b) By using the multilayer film whose surface roughness is low relative to the thickness as the implantation mask, it is possible to reduce an effect of the surface scattering during the ion implantation.
(c) By controlling the number of times that the substrate (wafer) is exposed to the crystal growth inhibiting gas when forming the multilayer film, it is possible to control the residual stress in the multilayer film. In addition, by appropriately combining with the annealing step, it is possible to prevent a collapse of the implantation mask and the substrate warpage.
(d) In addition, since the annealing step is not performed when forming the multilayer film and the process temperature is not changed, it is possible to shorten the process time. Thereby, it is possible to improve the throughput, in particular, in a process using a vertical type apparatus.

### (4) Modified Examples

The step B in the embodiments described above can be modified as shown in modified examples described below. Unless otherwise specified, process procedures and process conditions in each step of each modified example may be substantially the same as the process procedures and the process conditions in each step of the embodiments described above.

According to the present modified example, in the step B described above, a predetermined gas capable of forming a film (or surface) whose film quality is different from that of the polycrystalline film 31a formed in the step A is used instead of the crystal growth inhibiting gas. That is, the substrate processing apparatus described above is provided with a predetermined gas supply system configured to expose the wafer 200 in the process chamber 201 to the predetermined gas capable of forming the film whose film quality is different from that of the polycrystalline film 31a, and the following process sequence is performed.
Source gas→Predetermined gas)×n

For example, the predetermined gas is a gas containing a Group 14 element. That is, a constituent element of the polycrystalline film 31a formed in the step A and a constituent element of the film (whose film quality is different from that of the polycrystalline film 31a) formed in the step B may be substantially the same. For example, a composition of the film formed in the step B may be the same composition as the initial film formed in the step A except for the crystallinity alone.

Specifically, for example, in the step B, by supplying a silicon source gas (such as disilane (Si₂H₆) gas or chlorosilane gas) other than the SiH₄ gas mentioned above, an amorphous silicon film (whose film quality is different from that of the polycrystalline film 31a formed on the wafer 200 in step A, may be formed. By using a source gas different from the source gas used in the step A, it is possible to change the crystallinity without changing the temperature.

According to the present modified example, it is also possible to obtain substantially the same effects as in the embodiments mentioned above. In addition, according to the present modified example, since the gas containing the same elements as those contained in the source gas used in the step A can be used in the step B, it is possible to prevent the multilayer film from containing elements different from those contained in the source gas.

Alternatively, the steps A and B may be performed in parallel without being separated (that is, the steps A and B may be performed simultaneously). In such an operation, during a progress of a deposition, a predetermined gas different from the source gas is supplied along with the source gas such that the crystal grain size (cross-sectional area in a plane parallel to the substrate) does not change and/or the orientation is equal, that is, the crystallinity is constant. In such an operation, a partial pressure of the source gas, a partial pressure of the predetermined gas exposed along with the source gas or the temperature of the wafer 200 may be changed. Even in such a case, it is possible to maintain a gradient of the residual stress of the polycrystalline film 31a within a predetermined range, and it is also possible to process the polycrystalline film 31a into a cantilever while maintaining the gradient of the residual stress of the polycrystalline film 31a within the predetermined range. According to the present modified example, as the predetermined gas exposed along with the source gas, for example, a gas such as the inert gas (for example, the N₂ gas or the Ar gas) and the H₂ gas may be used.

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

For example, the technique of the present disclosure is not limited to a case where the super junction structure is formed by a single execution of the ion implantation, and may be combined with a conventional multi-step epitaxial method. For example, a part of a conventional multilayer epitaxial layer may be formed using the steps S1 through S7 of the technique of the present disclosure. In such a case, it is possible to reduce the number of steps as compared with the conventional method.

In addition, for example, the initial film formed in the step A of the step S2 is not limited to the polycrystalline film, and may be an amorphous film or a single-crystalline film. In addition, for example, the film formed in the step B may be appropriately selected from an amorphous film and a polycrystalline film whose crystallinity is different from that of the initial film formed in the step A. When the initial film is the amorphous film, the film (which is stacked) can easily become polycrystalline by annealing at 600° C. or higher. In such a case, the step B can contribute to a nucleation, a grain boundary formation, and a grain size control. In addition, it is sufficient that the film formed in the step B differs from the surface state of the film during the step A in at least one atomic layer of the surface, and the film formed in the step B may not be a continuous film. That is, the step B is not limited to depositing a new film on the initial film deposited in the step A, and the step B may involve reconstructing a surface of the initial film, sparsely (or non-uniformly) adsorbing specific molecules to a small portion of the surface, modifying the surface through a chemical reaction, breaking atomic bonds or exciting the surface. According to such a case, it is also possible to obtain substantially the same effects as in the embodiments mentioned above.

For example, a material constituting the starting substrate 11 is not limited to silicon carbide (SiC), and a material such as silicon (Si), gallium nitride (GaN), digallium trioxide (Ga₂O₃) and zinc oxide (ZnO) may also be used.

The process recipe is not limited to creating a new recipe. For example, the recipe may be prepared by changing an existing recipe stored (or installed) in the substrate processing apparatus in advance. When changing the existing recipe to a new recipe, the new recipe may be installed in the substrate processing apparatus via an electric communication line or a recording medium in which the new recipe is stored. Further, the existing recipe already stored in the substrate processing apparatus may be directly changed to the new recipe by operating the input/output device 122 of the substrate processing apparatus.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments mentioned above. Even in such a case, it is possible to obtain substantially the same effects as in the embodiments mentioned above.

In addition, the embodiments and the modified examples mentioned above may be appropriately combined. The process procedures and the process conditions of each combination thereof may be substantially the same as those of the embodiments mentioned above or the modified examples mentioned above.

Further, the entire contents of Japanese Patent Application No. 2024-038963, filed on Mar. 13, 2024, are hereby incorporated in the present specification by reference. All documents, patent applications, and technical standards described in the present specification are hereby incorporated in the present specification by reference to the same extent that the contents of each of the documents, the patent applications and the technical standards are specifically described.

According to some embodiments of the present disclosure, it is possible to use the mask when performing the ion implantation of the high energy.

What is claimed is:

1. A substrate processing method comprising:
(a) forming a multilayer film of a predetermined thickness with a controlled grain size on a substrate by performing a cycle a predetermined number of times, and patterning the multilayer film to prepare the substrate provided with a patterned multilayer film, wherein the cycle comprises:
(a-1) depositing a first film by exposing the substrate provided with a drift layer formed thereon to a source gas; and
(a-2) exposing the substrate to a crystal growth inhibiting gas or a predetermined gas capable of forming a second film whose film quality is different from that of the first film; and
(b) performing an ion implantation using the patterned multilayer film as a hard mask,
wherein the multilayer film is more easily etched than the drift layer.

2. The substrate processing method of claim 1, wherein (a) is performed in a hot wall type and batch type process chamber, and
wherein the predetermined number of times is set such that an average grain size of crystals in the multilayer film is equal to or smaller than a predetermined value.

3. The substrate processing method of claim 1, the predetermined number of times is set such that an absolute value or a gradient of a residual stress of the multilayer film when the multilayer film is exposed on a surface of the substrate is equal to or smaller than a predetermined value.

4. The substrate processing method of claim 1, further comprising:
(c) annealing the multilayer film before (b).

5. The substrate processing method of claim 1, wherein the first film is a polycrystalline film containing at least one of silicon and germanium as a main constituent element, and two crystal grains of the first film separated by performing (a-2) are independent from each other.

6. The substrate processing method of claim 1, wherein an average grain size of each of a plurality of first films formed by performing the cycle the predetermined number of times is substantially same.

7. The substrate processing method of claim 1, wherein the first film is a polycrystalline or amorphous film whose average grain size is 0.2 μm or less.

8. The substrate processing method of claim 1, wherein the substrate is a silicon carbide substrate.

9. The substrate processing method of claim 1, wherein the first film is a polycrystalline or amorphous film whose average grain size is 0.2 μm or less.

10. The substrate processing method of claim 1, wherein the predetermined thickness is set to be within a range from 1 μm to 20 μm such that the multilayer film retains a stopping power corresponding to a mask for the ion implantation of 1 MeV to 20 MeV.

11. The substrate processing method of claim 1, wherein an absolute value of a residual stress in the multilayer film is 100 MPa or less.

12. The substrate processing method of claim 1, wherein a surface roughness (Ra) of the multilayer film is 15 nm or less.

13. The substrate processing method of claim 1, wherein the substrate prepared in (a) is provided with a buffer layer below the multilayer film.

14. The substrate processing method of claim 1, further comprising:
(d) removing the multilayer film after (b); and
(e) annealing the substrate after (d) to activate impurities implanted in (b).

15. The substrate processing method of claim 1, wherein, in (b), a conductivity type is inverted by the ion implantation to form a well with a depth of 3 μm or more in a silicon carbide film.

16. A method of manufacturing a semiconductor device, comprising:
(a) forming a multilayer film of a predetermined thickness with a controlled grain size on a substrate by performing a cycle a predetermined number of times, and patterning the multilayer film to prepare the substrate provided with a patterned multilayer film, wherein the cycle comprises:
(a-1) depositing a first film by exposing the substrate provided with a drift layer formed thereon to a source gas; and
(a-2) exposing the substrate to a crystal growth inhibiting gas or a predetermined gas capable of forming a second film whose film quality is different from that of the first film; and
(b) activating impurities by annealing the substrate after the impurities are implanted by an ion implantation using the patterned multilayer film as a hard mask.

17. The method of claim 16, wherein a well formed by inverting a conductivity type with the impurities activated in (b) constitutes a super junction structure of a MOSFET.

18. A method of forming a hard mask for an ion implantation, comprising:
forming a multilayer film whose thickness is within a range from 1 μm to 20 μm on a substrate by performing a cycle a predetermined number of times, wherein the cycle comprises:
(a) depositing a first film which is polycrystalline or amorphous by exposing the substrate made of silicon carbide or gallium nitride to a source gas; and
(b) exposing the substrate to a crystal growth inhibiting gas or a predetermined gas capable of forming a second film whose film quality is different from that of the first film,
wherein two crystal grains of the first film separated by performing (b) are independent from each other.

19. A substrate processing apparatus comprising:
a process chamber; and
a controller configured to be capable of controlling an execution of the method of claim

18. performed in the process chamber.

20. A non-transitory computer-readable recording medium storing a program that causes, by a computer, a substrate processing apparatus to perform a process comprising the method of claim 18.
